(19) United States
(12) Patent Application Publication
(10) Pub. No.: US 2025/0393318 A1
(43) Pub. Date: Dec. 25, 2025

(54) METHODS FOR IMPROVING IMAGE LAG IN IMAGE SENSOR

(71) Applicant: Taiwan Semiconductor Manufacturing Company, LTD., Hsinchu (TW)

(72) Inventors: Yi-Liang Lin, Hsinchu (TW); Chia-Chan Chen, Zhubei (TW); Shiuan-Jeng Lin, Hsinchu (TW); Yueh-Chuan Lee, Hsinchu (TW)

(21) Appl. No.: 18/749,920

(22) Filed: Jun. 21, 2024

(51) Int. Cl. H01L 27/146

(52) U.S. Cl. CPC H10F 39/014; H10F 39/18; H10F 39/803

(57) ABSTRACT

An image sensor includes a ridge between a photodiode and a floating node. A three-sided gate structure is present around the ridge, and includes two buried gate regions. This shape increases the effective gate width, and creates a deep channel to permit the signal stored in the photodiode to more thoroughly drain out to the floating node. This improves or reduces image lag or afterimage of the image sensor.

### BACKGROUND

Image sensors convert incoming light (photons) into a digital signal for image capture and analysis. This is useful in various applications such as binoculars, cameras (handheld, still, or video), telescopes, and cellphones/smartphones, optical mice for computer input, medical imaging equipment, night vision equipment, and others. Various structures are still being researched to further improve performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a plan view of a semiconductor device such as an image sensor, in accordance with some embodiments of the present disclosure.

FIG. 1B is a Y-axis cross-sectional view through the ridge, through line B-B of FIG. 1A.

FIG. 1C is a plan cross-sectional view of the device through line C-C of FIG. 1B.

FIG. 1D is an X-axis cross-sectional view of a first embodiment of the device through line D-D of FIG. 1A. FIG. 1E is an X-axis cross-sectional view of a second embodiment of the device through line D-D of FIG. 1A. FIG. 1F is an X-axis cross-sectional view of a third embodiment of the device through line D-D of FIG. 1A. They differ in the shape of the buried gate regions of the gate structure.

FIG. 1G is a Y-axis cross-sectional view of the photodiode through line G-G of FIG. 1A.

FIG. 1H is a Y-axis cross-sectional view of the floating node through line H-H of FIG. 1A.

FIG. 2 is a flow chart illustrating a method for making a semiconductor device, in accordance with some embodiments.

FIG. 3A is a plan view and FIG. 3B is a Y-axis cross-sectional view of the device through line B-B of FIG. 3A, after trenches are formed in the substrate to define a ridge.

FIG. 4A is a plan view and FIG. 4B is a Y-axis cross-sectional view of the device through line B-B of FIG. 4A, after the trenches are filled to form isolation region(s).

FIG. 5A is a plan view and FIG. 5B is a Y-axis cross-sectional view of the device through line B-B of FIG. 5A, after a recess is formed in the ridge.

FIG. 6A is a plan view and FIG. 6B is a Y-axis cross-sectional view of the device through line B-B of FIG. 6A, after gate trenches are formed in the isolation region(s) to expose the sides of the ridge.

FIG. 7A is a plan view and FIG. 7B is a Y-axis cross-sectional view of the device through line B-B of FIG. 7A, after a gate dielectric layer is formed on the ridge.

FIG. 8A is a plan view and FIG. 8B is a Y-axis cross-sectional view of the device through line B-B of FIG. 8A, after a gate material is deposited into the two gate trenches and over the ridge to form a gate structure.

FIG. 9A is a plan view and FIG. 9B is a Y-axis cross-sectional view of the device through line B-B of FIG. 9A, after the gate structure is patterned to obtain a desired shape.

FIG. 10A is a plan view and FIG. 10B is an X-axis cross-sectional view of the device through line D-D of FIG. 10A, after the photodiode is formed.

FIG. 11A is a plan view and FIG. 11B is an X-axis cross-sectional view of the device through line D-D of FIG. 11A, after the floating node is formed.

FIG. 12A is a plan view and FIG. 12B is a Y-axis cross-sectional view of the device through line B-B of FIG. 12A, after dielectric spacers are formed around a capping region of the gate structure above the ridge.

FIG. 13 is an X-axis cross-sectional view of the device through line D-D of FIG. 1A after formation of other layers of the image sensor.

FIG. 14 is a plan view of another embodiment of a semiconductor device such as an image sensor, in accordance with some embodiments of the present disclosure. Here, multiple photodiodes may share a common floating node.

FIG. 15 is a flow chart illustrating a method for using an image sensor, in accordance with some embodiments.

FIG. 16 is a cross-sectional view of an image signal processor (ISP) semiconductor package which is connected to a CMOS image sensor (CIS) package.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g., “about 2 to about 4” also discloses the range “from 2 to 4.” The term “about” may refer to plus or minus 10% of the indicated number.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example all layers of the structure can be considered to be “on” the substrate, even though they do not all directly contact the substrate. The term “directly” may be used to indicate two layers directly contact each other without any layers in between them. In addition, when referring to performing process steps to the substrate or upon the substrate, this should be construed as performing such steps to whatever layers may be present on the substrate as well, depending on the context.

The present disclosure relates to gate structures that are particularly useful in semiconductor devices, such as image sensors, for various applications. The image sensor may be, for example, a charge-coupled device (CCD) or an active-pixel sensor (CMOS sensor). Incoming light signals of a particular wavelength (visible, UV, X-ray, charged particles, etc.) are converted to an electrical signal (usually electrons) and collected/stored in a photodiode. The electrical signal is then transferred to a floating node and read. If the electrical signal is not completely transferred in one frame, then image lag will occur as the residual electrons are transferred in subsequent frame. This manifests as smearing or blurring of the image. In the present disclosure, a gate structure creates a deep channel to permit the signal stored in the photodiode to more thoroughly drain out. This improves or reduces the image lag or afterimage.

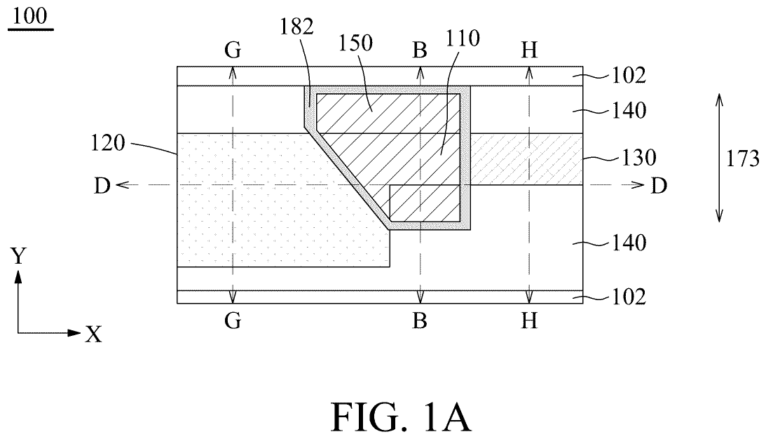

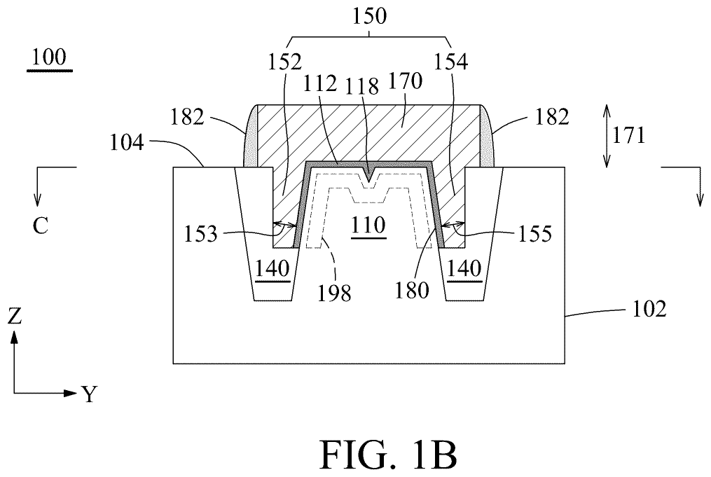

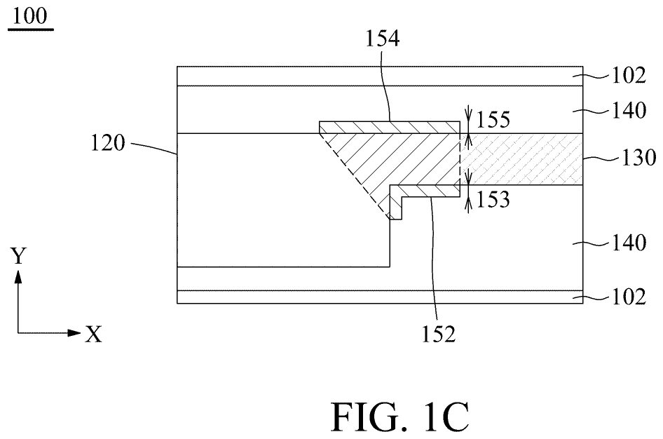

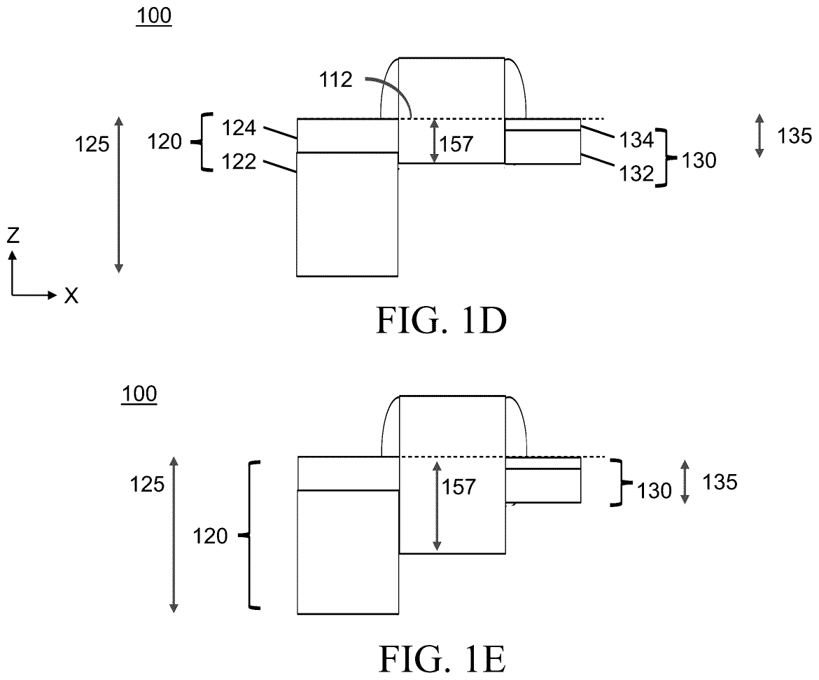

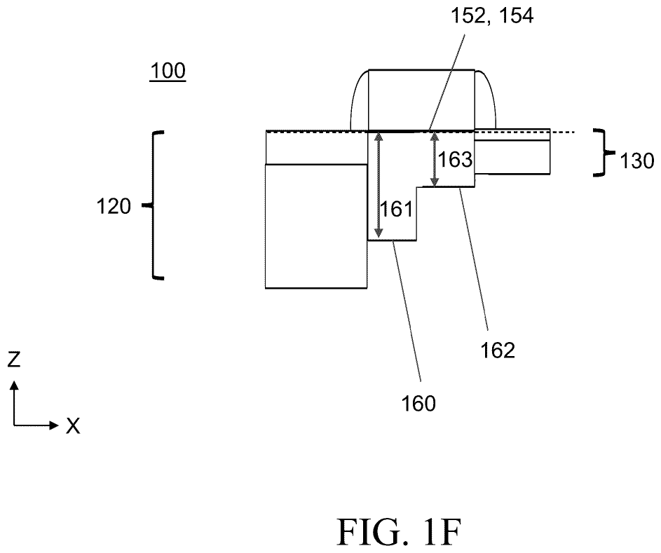

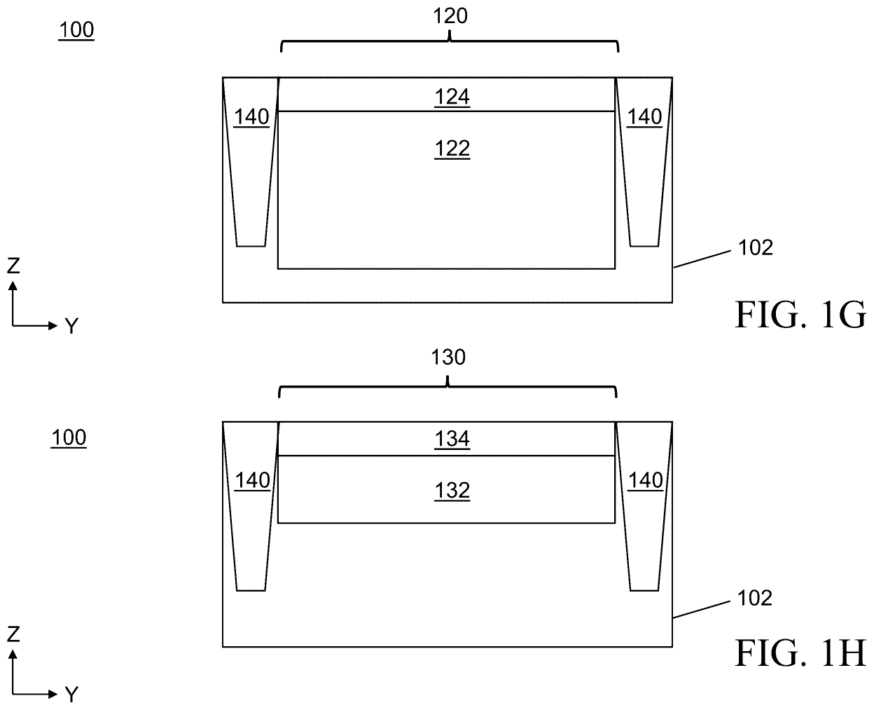

FIG. 1A is a top plan view of a semiconductor device 100, in accordance with some embodiments of the present disclosure. FIG. 1B is a Y-axis cross-sectional view of the gate structure through the ridge, through line B-B of FIG. 1A.

Referring to both FIG. 1A and FIG. 1B, the semiconductor device 100 is formed within and upon a substrate 102. A ridge 110 electrically connects a photodiode 120 to a floating node 130. Two isolation regions 140 are illustrated as being present on opposite sides of the ridge 110. However, it is noted that these two isolation regions may be connected to each other at other points on the substrate.

A gate structure 150 is present over the ridge 110. As better seen in FIG. 1B, the gate structure comprises two buried gate regions 152, 154 and a capping region 170 over the ridge 110. The buried gate regions are located below the upper surface 104 of the substrate, and the capping region is located above the upper surface. The gate structure can thus be described as covering three sides of the ridge.

A gate dielectric layer 180 contacts the gate structure 150 and the ridge 110, and is located between them. The gate structure may also be described as covering three sides of the ridge. If desired, one or more recesses 118 may be made into the ridge. Here, one recess is present in the upper surface 112 of the ridge. This can increase the surface area between the gate structure and the ridge, improving control. At least one dielectric spacer 182 surrounds the capping region 170 of the gate structure 150. When the gate structure is activated, a channel 198 is created between the photodiode and the floating node, which is larger and deeper than a channel that would be created solely by the capping region 170.

Referring to FIG. 1B, the capping region 170 may have a height 171 of about 1000 angstroms to about 3000 angstroms. The widths 153, 155 of the two buried gate regions may independently be from about 1000 angstroms to about 3000 angstroms. Their width is measured perpendicularly from the respective surface of the ridge. However, other ranges and values are within the scope of the present disclosure.

FIG. 1C is a plan cross-sectional view of the device 100 through line C-C of FIG. 1B. As can be seen by comparing FIG. 1A to FIG. 1C, the capping region 170 of the gate structure can have a different width 173 than the width 153, 155 of the two buried gate regions 152, 154. In addition, the buried gate regions 152, 154 may be shaped differently from each other. In this plan view, buried gate region 154 is in the shape of a straight line, whereas buried gate region 152 is L-shaped.

FIG. 1D is an X-axis cross-sectional view of a first embodiment of the device 100 through line D-D of FIG. 1A. As better seen here, the photodiode 120 is formed from the combination of a deep doped region 122 and a shallow doped region 124. The deep doped region is formed by doping with a first dopant type. The shallow doped region is formed by doping with a second dopant type. The first dopant type and the second dopant type are of opposite charge. For example, if the first dopant type is an n-type dopant, then the second dopant type is a p-type dopant, and vice versa. Similarly, the floating node 130 is formed from the combination of a deep doped region 132 and a shallow doped region 134. However, the deep doped region is formed by doping with the second dopant type, and the shallow doped region is formed by doping with the first dopant type.

Continuing, the photodiode has a depth 125, and the floating node has a depth 135. In particular embodiments, the depth 125 of the photodiode is greater than the depth 135 of the floating node. In some cases, the depth 125 of the photodiode may be from about two (2) to about ten (10) times greater than the depth 135 of the floating node. However, other ranges and values are within the scope of the present disclosure. For example, the photodiode may have a depth of about 1000 angstroms, and the floating node may have a depth of about 200 angstroms.

The depth 157 of the buried gate regions is also indicated, and is measured from the upper surface 112 of the ridge. As illustrated in FIG. 1D, the depth 157 of the buried gate regions is about equal to the depth 135 of the floating node. In particular embodiments, the ratio of the depth 157 of the buried gate regions to the depth 125 of the photodiode may be from about 1:100 to about 100:100. In other particular embodiments, the ratio of the depth 157 of the buried gate regions to the depth 125 of the photodiode may be from about 5:100 to about 100:100, or from about 10:100 to about 100:100, or from about 20:100 to about 100:100, or from about 25:100 to about 100:100, or from about 40:100 to about 100:100, or from about 50:100 to about 100:100, or from about 10:100 to about 90:100, or from about 20:100 to about 80:100, or from about 25:100 to about 75:100, or from about 10:100 to about 50:100. Any combination of these endpoints is also contemplated, and other ranges and values may also fall within the scope of the present disclosure.

FIG. 1E is an X-axis cross-sectional view of a second embodiment of the device through line D-D of FIG. 1A. Here, the depth 157 of the buried gate regions is greater than the depth 135 of the floating node 130. The depth 157 of the buried gate regions is less than the depth 125 of the photodiode 120.

FIG. 1F is an X-axis cross-sectional view of a third embodiment of the device through line D-D of FIG. 1A. Here, the buried gate region 152, 154 may be described as being formed from at least two portions, a first portion 160 proximate the photodiode 120 and a second portion 162 proximate the floating node 130. As can be seen here, the first portion has a depth 161 which is greater than the depth 163 of the second portion. In some particular embodiments, the ratio of the second portion depth 163 to the first portion depth 161 may be from about 1:1 to about 1:5, or from about 1:1 to about 1:2. Of course, if the ratio is 1:1, then the buried gate region is as illustrated in FIG. 1D and FIG. 1E.

FIG. 1G is a Y-axis cross-sectional view of the photodiode 120 through line G-G of FIG. 1A. Again, the photodiode is formed from the combination of a deep doped region 122 and a shallow doped region 124. The deep doped region is doped with the first dopant type, and the shallow doped region is doped with the second dopant type. One or more isolation regions 140 are also present around the photodiode.

FIG. 1H is a Y-axis cross-sectional view of the floating node 130 through line H-H of FIG. 1A. Again, the floating node is formed from the combination of a deep doped region 132 and a shallow doped region 134. The deep doped region is doped with the second dopant type, and the shallow doped region is doped with the first dopant type. One or more isolation regions 140 are also present around the floating node.

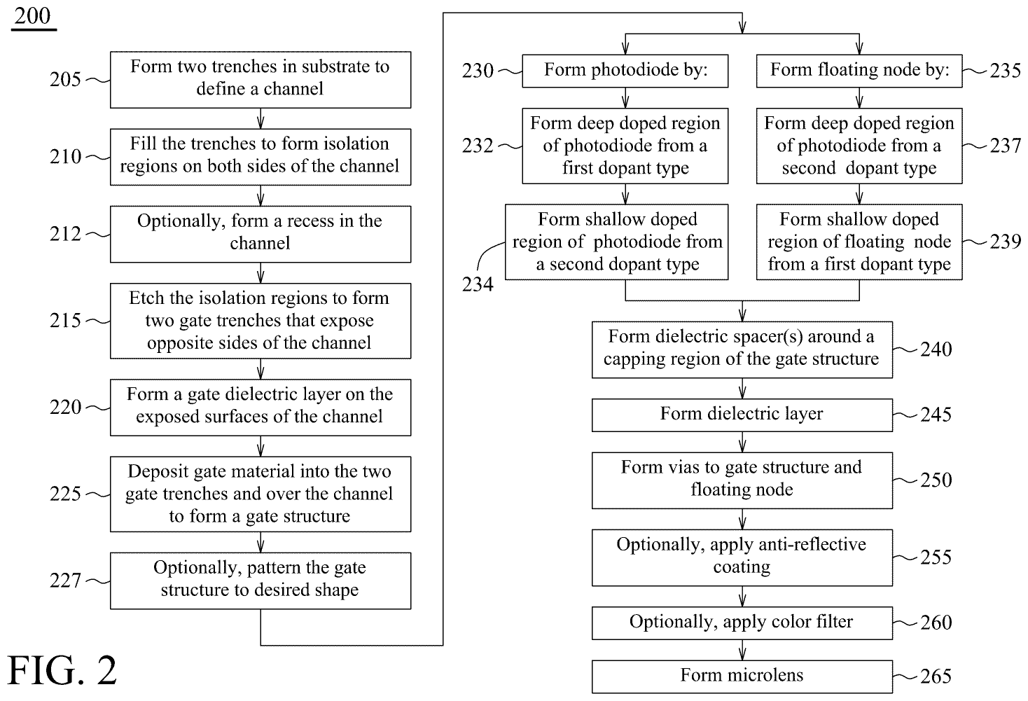

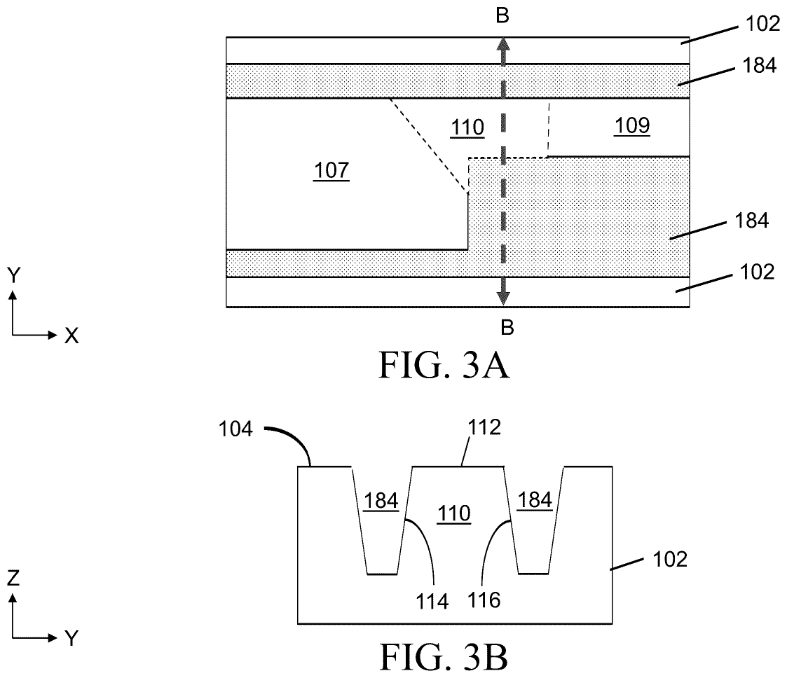

FIG. 2 is a flow chart illustrating a method 200 for making a semiconductor device, in accordance with some embodiments. Some steps of the method are also illustrated in FIGS. 3A-13. These figures provide different views for better understanding. While the method steps are discussed below in terms of forming a single semiconductor device, such discussion should also be broadly construed as applying to the concurrent formation of multiple semiconductor devices. Other structures may also be concurrently formed, and additional layers may also be formed between the various components shown herein.

Initially, in step 205 of FIG. 2 and as illustrated in FIG. 3A and FIG. 3B, a substrate 102 is patterned to form two trenches 184 in the substrate. As a result, a ridge 110 is formed or defined between a photodiode region 107 and a floating node region 109.

The substrate 102 may be, for example, a wafer made of a semiconducting material. Such semiconductor materials can include silicon, for example in the form of crystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the substrate is made of silicon.

The ridge 110 is indicated in dashed lines in FIG. 3A. The photodiode region 107 and the floating node region 109 are also present in the substrate, and may be any arbitrary shape desired. The upper surface of the substrate is indicated with reference numeral 104 in FIG. 3B. The three sides 112, 114, 116 of the ridge are also indicated.

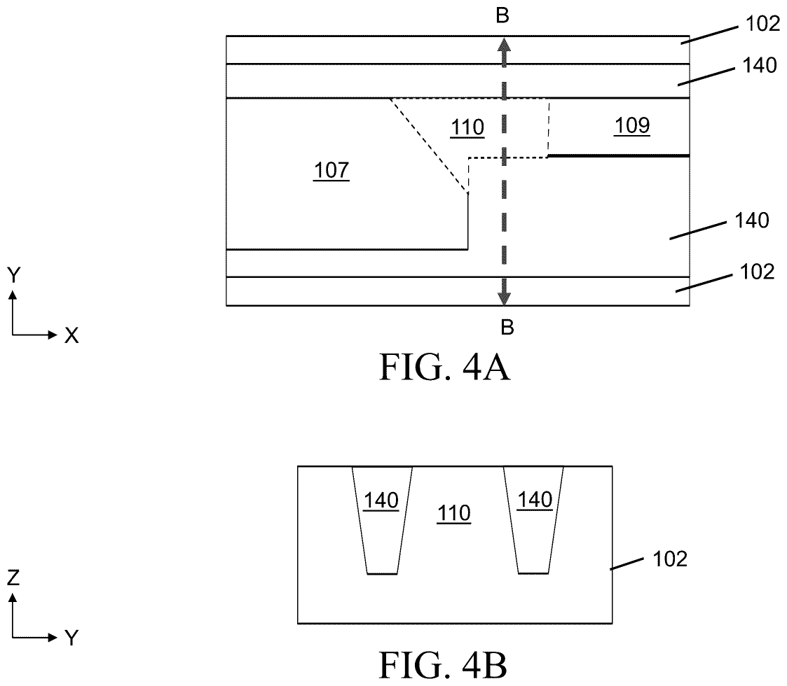

Next, in step 210 of FIG. 2 and as illustrated in FIG. 4A and FIG. 4B, the two trenches are filled with a dielectric material to form isolation regions 140 on either side of the ridge 110. These may be considered to be shallow trench isolation (STI) regions. As previously mentioned, when considered in three dimensions, the two STI regions may be linked to each other and could be considered as one isolation region.

The isolation regions are formed by patterning the substrate, etching the trenches, and filling the trenches with a dielectric material. The dielectric material in the isolation regions is commonly silicon dioxide, although other dielectric materials can also be used such as undoped polysilicon, silicon nitride, silicon oxynitride, fluoride-doped silicate glass, or another high-k or low-k dielectric material. The deposition can be done using physical vapor deposition (PVD) or chemical vapor deposition (CVD) or spin-on processes known in the art, or can be grown via oxidation. If desired, the dielectric material can be deposited to a level above that of the substrate upper surface 104, then recessed back down to the desired height.

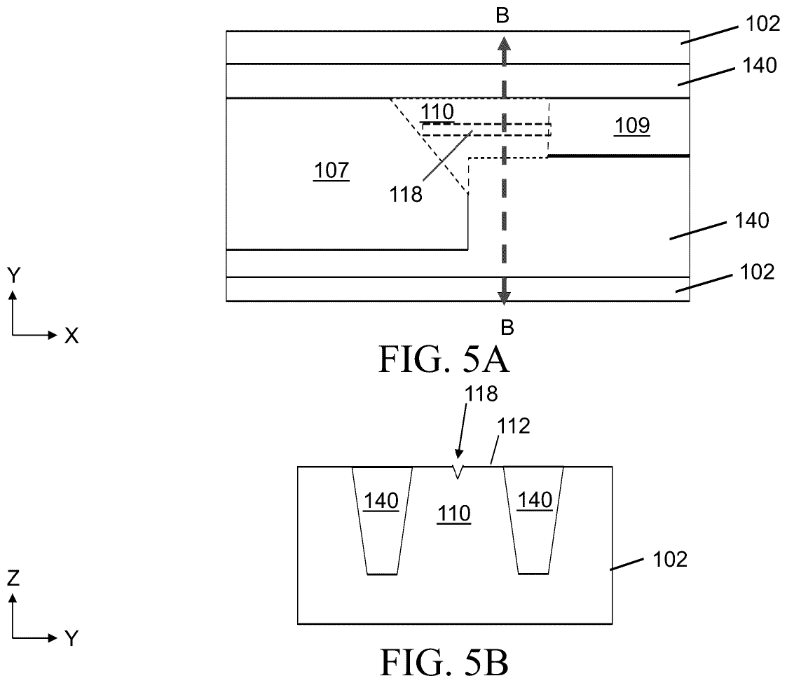

If desired, then in optional step 212 of FIG. 2 and as illustrated in FIG. 5A and FIG. 5B, a recess 118 may be formed in the ridge 110. As illustrated here, the recess is formed in the upper surface 112 of the ridge 110.

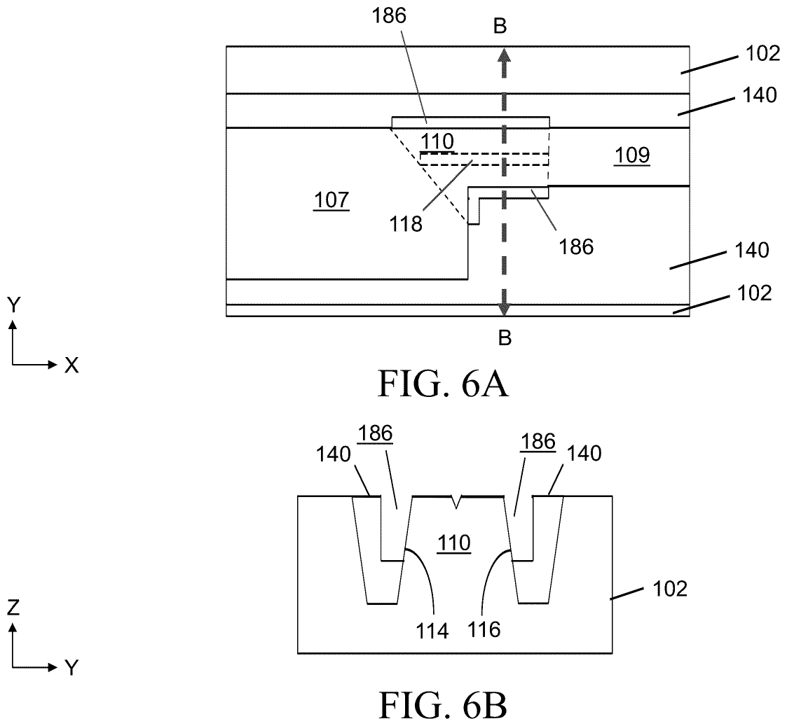

Then, in step 215 of FIG. 2 and as illustrated in FIG. 6A and FIG. 6B, two gate trenches 186 are formed in the isolation regions on opposite sides of the ridge 110. This is typically done by patterning and etching the isolation regions. These two gate trenches also expose the opposite sides 114, 116 of the ridge itself. It is noted that the two gate trenches do not extend to the bottom of the isolation regions 140, and the gate trenches are still separated from the rest of the substrate by the isolation regions 140. If it is desired to form buried gate regions with two portions as illustrated in FIG. 1F, the gate trenches can be formed in two separate etching steps (one for each portion).

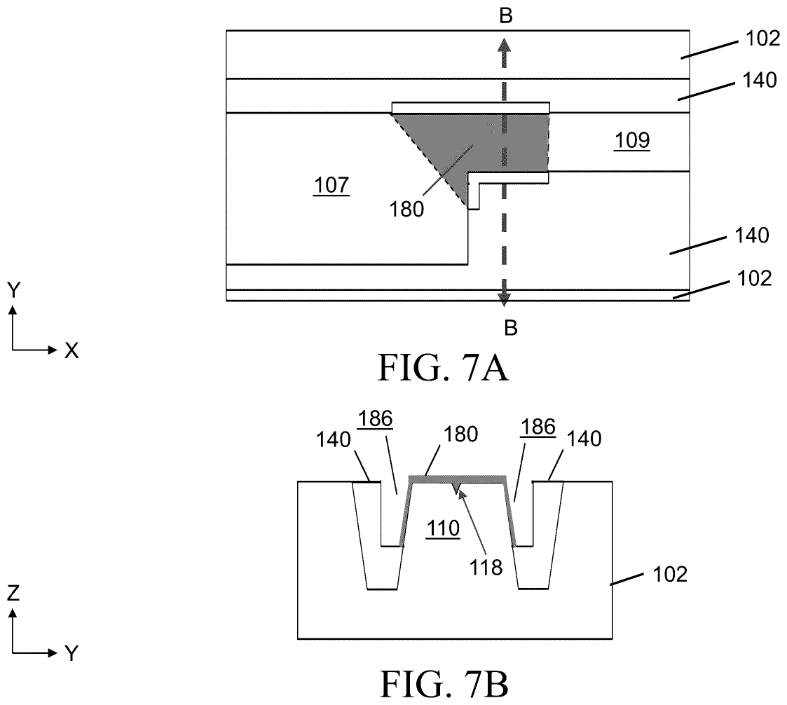

Next, in step 220 of FIG. 2 and as illustrated in FIG. 7A and FIG. 7B, a gate dielectric layer 180 is formed on the three exposed surfaces of the ridge 110. As illustrated here, the gate dielectric layer also fills the recess 118. The gate dielectric layer is, in particular embodiments, silicon dioxide, which can be grown via oxidation. In other embodiments, the gate dielectric layer may be deposited via CVD, PVD, or atomic layer deposition (ALD).

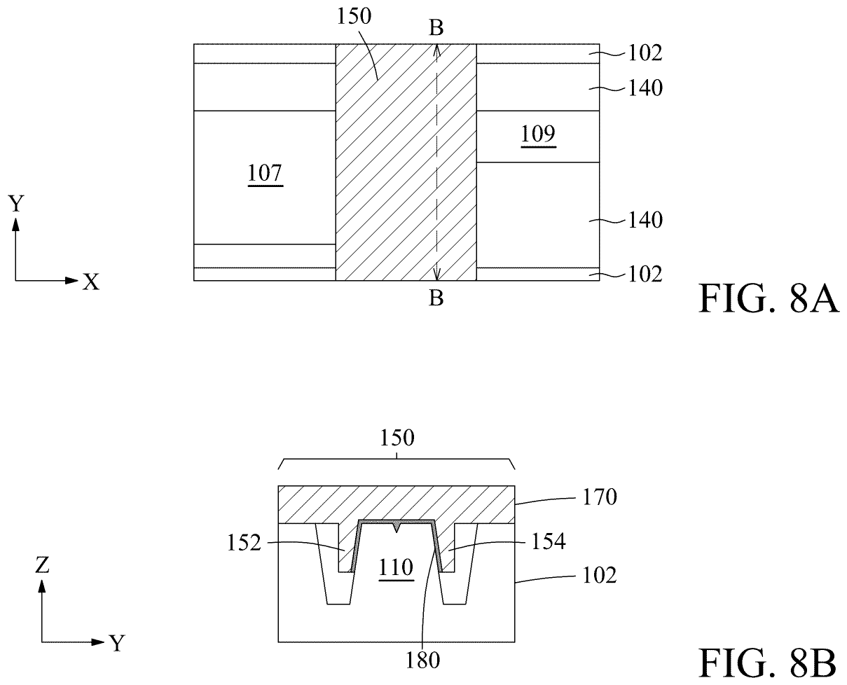

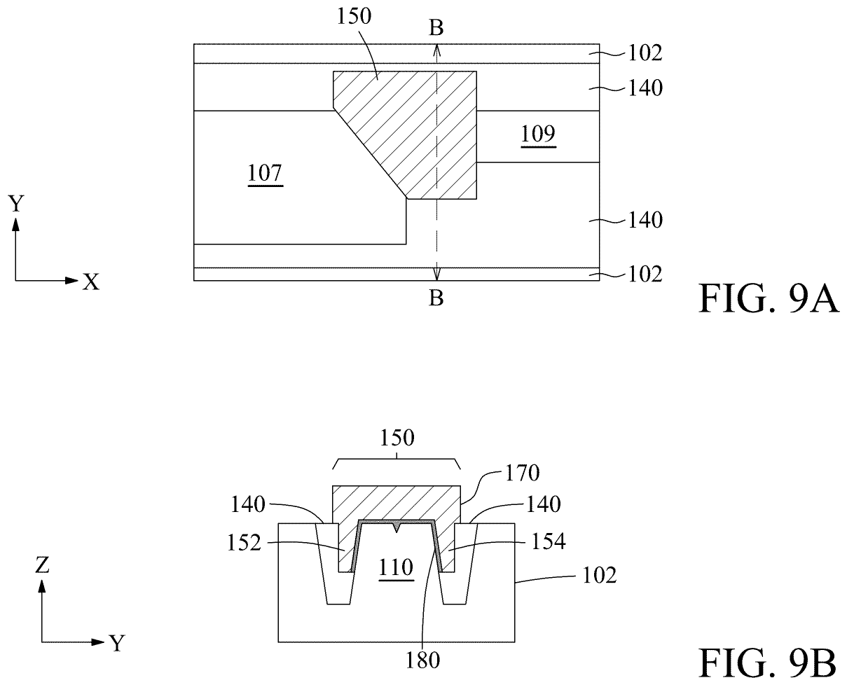

Then, in step 225 of FIG. 2 and as illustrated in FIG. 8A and FIG. 8B, a gate material is deposited into the two gate trenches and over the ridge 110 to form a gate structure 150. The gate structure includes two buried gate regions 152, 154 and a capping region 170 over the ridge. The two buried gate regions 152, 154 are formed in the two gate trenches of FIG. 7B. In optional step 227 of FIG. 2 and as illustrated in FIG. 9A and FIG. 9B, the gate structure 150 is patterned to obtain the final desired shape.

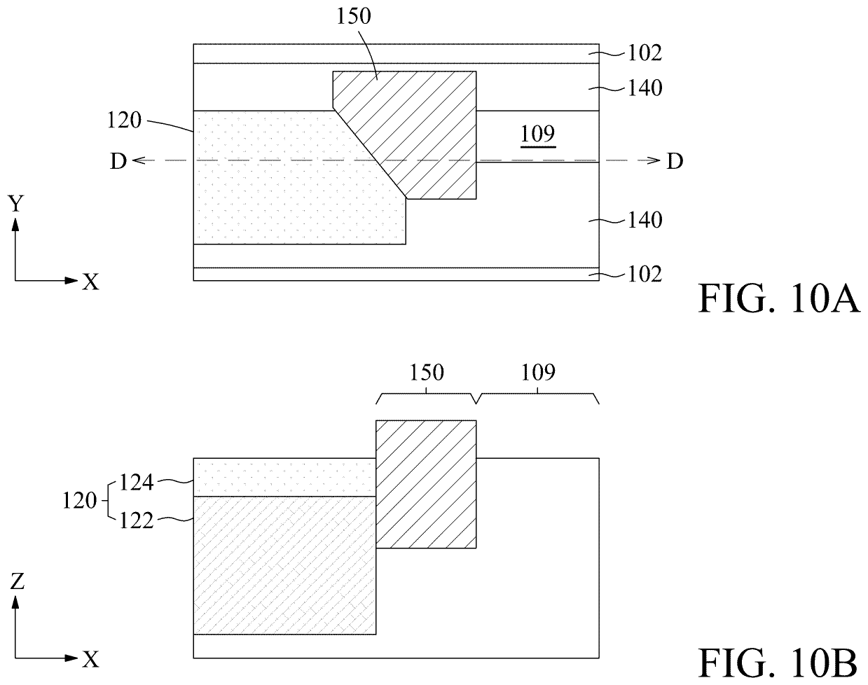

In step 230 of FIG. 2, a photodiode 120 is formed in the photodiode region. As illustrated in FIG. 10A and FIG. 10B, this may be done by doping the photodiode region with a first dopant type to form a deep doped region 122 in step 232. Then, in step 234, the photodiode region is doped with a second dopant type to form a shallow doped region 124.

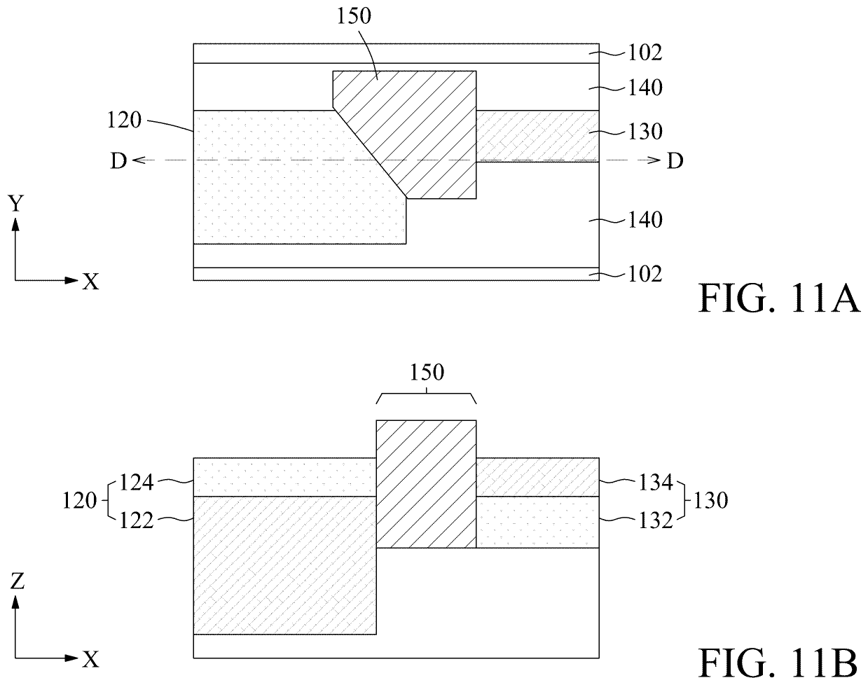

In step 235 of FIG. 2, a floating node 130 is formed in the floating node region. As illustrated in FIG. 11A and FIG. 11B, this may be done by doping the floating node with the second dopant type to form a deep doped region 132 in step 237. Then, in step 239, the floating node region is doped with the first dopant type to form a shallow doped region 134. It is noted that the photodiode 120 or the floating node 130 can be formed in either order, as indicated in FIG. 2. In addition, the deep doped region 122, 132 and the shallow doped region 124, 134 can be formed in either order as desired.

The first dopant type and the second dopant type are different from each other in their charge. Put another way, one doped region is negatively doped, and the other doped region is positively doped. In particular embodiments, the first dopant type is an n-type dopant, and the second dopant type is a p-type dopant. Common p-type dopants may include boron, gallium, or indium. Common n-type dopants may include phosphorus or arsenic.

The doping may be performed by ion implantation, which modifies the conductivity of the silicon crystal lattice in the implanted location. An ion implanter generally includes an ion source, a beam line, and a process chamber. The ion source produces desired ions which act as dopants to change various properties in desired locations of the base layer. The resulting ion beam enters the beam line, which organizes the ions into a beam having high purity in terms of ion mass, energy, and species. The ion beam is then used to irradiate the substrate in the process chamber. The dosage, energy, implant angle, and other parameters may be used to control the depth at which the dopant is implanted in the substrate.

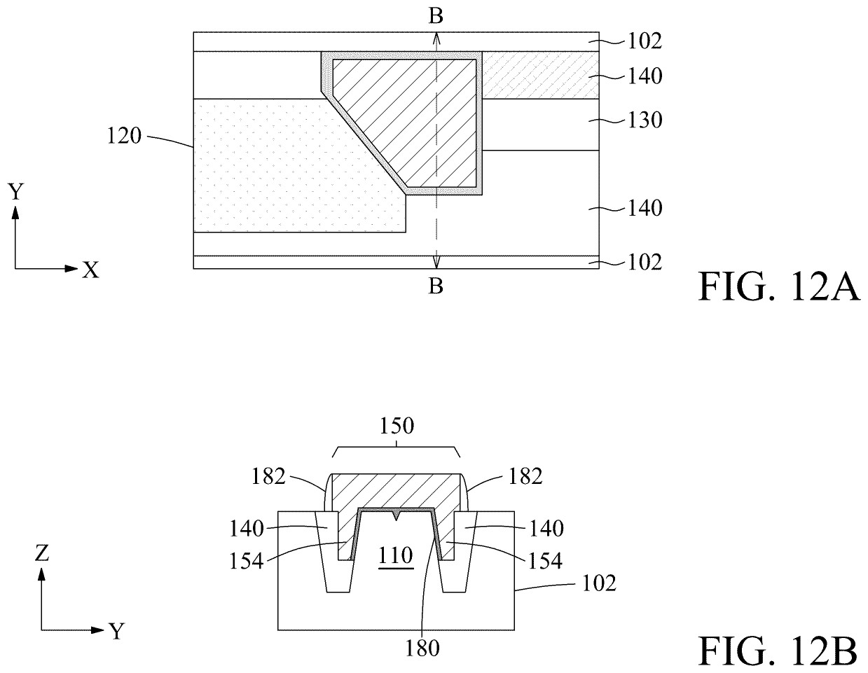

Continuing, in step 240 of FIG. 2 and as illustrated in FIG. 12A and FIG. 12B, one or more dielectric spacer(s) 182 are formed around the capping region 170 of the gate structure. This may be done, for example, by deposition, patterning, and etching of a dielectric material.

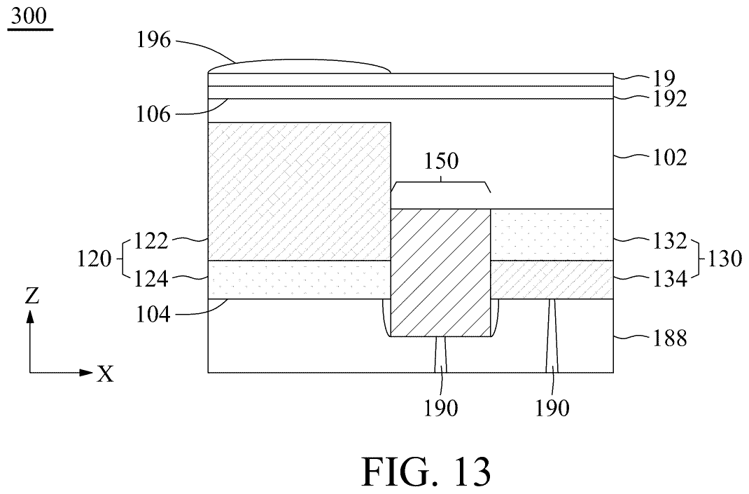

Additional processing steps may be performed to fully build out the image sensor 300, which is illustrated in FIG. 13. For example, in step 245 of FIG. 2, a dielectric layer 188 is formed over the upper surface 104 of the substrate. This covers the gate structure 150, the photodiode 120, and the floating node 130. This may be done by deposition such as PVD, CVD, or ALD. The dielectric layer 188 may be made from the same or different material as the dielectric spacer 182. In step 250 of FIG. 2, vias 190 are formed to the gate structure 150 and the floating node 130. The vias are made by etching an opening and then filling the opening with a conductive metal or alloy. The substrate is then flipped over, and various processing steps can be performed on the backside 106 of the substrate.

In optional step 255 of FIG. 2, an anti-reflective coating 192 is applied to the backside 106. This may be useful for reducing optical interference and thus increasing the efficiency and response of the photodiode. This may be done by deposition of suitable materials.

In optional step 260 of FIG. 2, a color filter 194 is applied to the backside 106. This may be used to filter the light by wavelength range and obtain information about the light intensity. The color filter may be formed by deposition of suitable materials.

In step 265 of FIG. 2, a microlens 196 may be formed on the backside 106. The microlens may be of a size and shape that is suitable for increasing the light collection efficiency of the image sensor by concentrating incident light on the sensor to the active area (i.e., photodiode), which covers only a part of the surface area of the entire image sensor. The microlens may be applied as a separate optical component, or can be made by deposition and patterning. The resulting structure is shown in FIG. 13.

The structures and methods of the present disclosure discussed above refer to dielectric layers. Such dielectric layers can generally be made from any suitable dielectric material or combination thereof, although the characteristics of any particular layer may also be further defined. Examples of dielectric materials may include silicon dioxide (SiO₂), silicon nitride (Si₃N₄), silicon carbide (SiC), hafnium dioxide (HfO₂), zirconium dioxide (ZrO₂), aluminum oxide (Al₂O₃), silicon oxynitride (SiOₓN_{y}), hafnium oxynitride (HfOₓN_{y}) or zirconium oxynitride (ZrOₓN_{y}), or hafnium silicates (HfSiₓO_{y}) or zirconium silicates (ZrSiₓO_{y}) or silicon carboxynitride (SiCₓO_{y}N_{z}), or hexagonal boron nitride (hBN). Other dielectric materials may include tantalum oxide (Ta₂O₅), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG). The dielectric layer may be formed by any suitable means, including chemical vapor deposition (CVD), physical vapor deposition (PVD), atomic layer deposition (ALD), thermal oxidation, or other suitable methods.

Any metal layer discussed herein may generally be formed from any conductive metal or conductive oxide. Examples of suitable metals may include copper, aluminum, nickel, chromium, gold, germanium, silver, titanium, tungsten, platinum, tantalum, ruthenium, cobalt, rhenium, palladium, or zirconium; composites like TiN, WN, or TaN; or alloys thereof like AlCu. Examples of suitable conductive oxides may include indium tin oxide (ITO), zinc oxide (ZnO), tin oxide (SnO), aluminum zinc oxide (AlZnO), indium oxide (InO), or cadmium oxide (CdO). The metal or oxide material may be deposited, for example, via evaporation or sputtering, plating, chemical vapor deposition (CVD), physical vapor deposition (PVD), atomic layer deposition (ALD), or other suitable methods.

It is also noted that certain conventional steps are not expressly described in the discussion above. For example, a pattern/structure may be formed in a given layer by applying a photoresist layer, patterning the photoresist layer, developing the photoresist layer to form a mask, and then etching through the mask to transfer the pattern to the given layer.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern (i.e., a mask). One example of a common developer is aqueous tetramethylammonium hydroxide (TMAH). Generally, any suitable developer may be used. Sometimes, a post develop bake or “hard bake” may be performed to stabilize the photoresist pattern after development, for optimum performance in subsequent steps.

Continuing, portions of the given layer below the patterned photoresist mask are now exposed. Etching transfers the photoresist pattern to the given layer below the patterned photoresist mask. After use, the mask can be removed, for example, using various solvents such as N-methyl-pyrrolidone (NMP) or alkaline media or other strippers at elevated temperatures, or by dry etching using oxygen plasma.

Generally, any etching step described herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

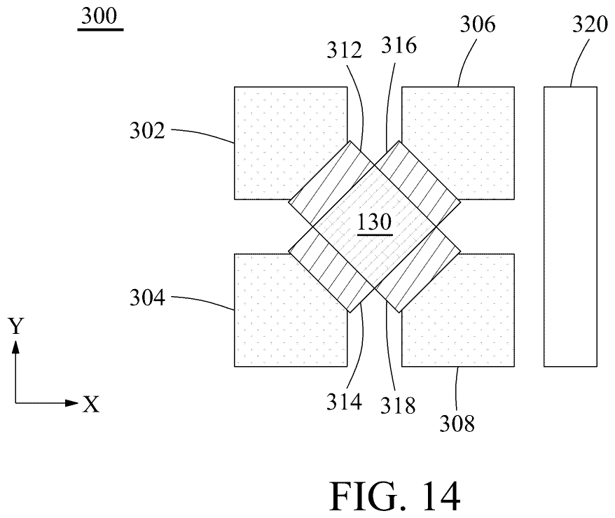

FIG. 14 is a plan view of another embodiment of an image sensor 300. In this embodiment, four photodiodes 302, 304, 306, 308 are illustrated along with four gate structures 312, 314, 316, 318. Each individual photodiode is electrically connected by an individual gate structure to the same floating node 130. The photodiodes are electrically isolated from each other. Each gate structure is located over a ridge as described above, and the gate structures are electrically isolated from each other. The four photodiodes share a common floating node 130. This configuration may also be electrically connected to other devices like capacitors or various transistors, such as a source follower transistor, a reset transistor, a row select transistor, or the like, which can be located in a device region 320 adjacent the photodiodes. Such a structure may be useful, for example, with a Bayer filter that uses two green-sensitive photodiodes, one red-sensitive photodiode, and one blue-sensitive photodiode.

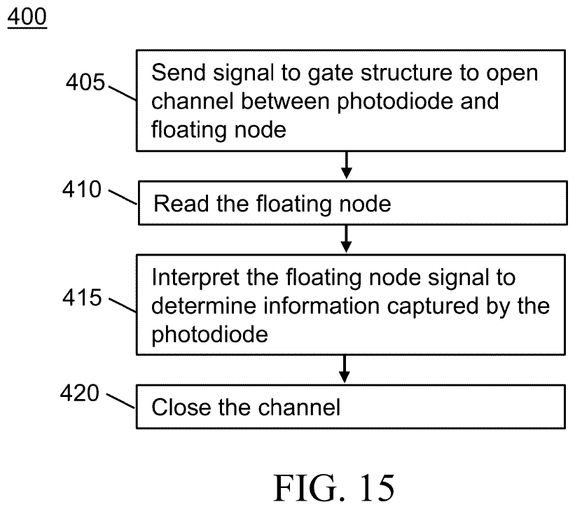

FIG. 15 is a flow chart illustrating a method 400 for using an image sensor, in accordance with some embodiments. The method steps are discussed below in terms of using a single image sensor, and should also be broadly construed as applying to the concurrent use of multiple image sensors. Reference is also made to the structure of FIG. 1A, FIG. 1B, and FIG. 13.

Initially, the photodiode stores an electrical charge. In step 405 of FIG. 15, a signal is sent to a gate structure 150. Typically, a voltage signal is sent, either in the form of an increased voltage or a decreased voltage (depending on how the gate structure is operated). This opens a channel 198 between the photodiode 120 and the floating node 130, which permits current to flow from the photodiode 120 to the floating node 130. The channel is present in the ridge 110, which is located in the substrate and is surrounded on three sides by a gate dielectric layer 180 and a gate structure 150. The gate structure comprises two buried gate regions 152, 154 and a capping region 170 over the ridge. In step 410, the floating node is then read, and in step 415 the signal from the floating node is interpreted by an image processing chip to determine parameters captured by the photodiode. Non-limiting examples of such parameters may include the color (wavelength) and brightness. When the voltage signal ceases, the channel 198 is closed, as indicated in step 420.

The image sensors of the present disclosure may be incorporated into larger semiconductor packages. Such packages may also include various interconnect structures. Various applications for the image sensors may include image signal processors (ISP); LCD, OLED, AMOLED, or QLED display panels; image sensors that can be used in systems such as mobile telephones, facial recognition systems, or as motion sensors for automotive applications, security applications, energy efficiency, etc.

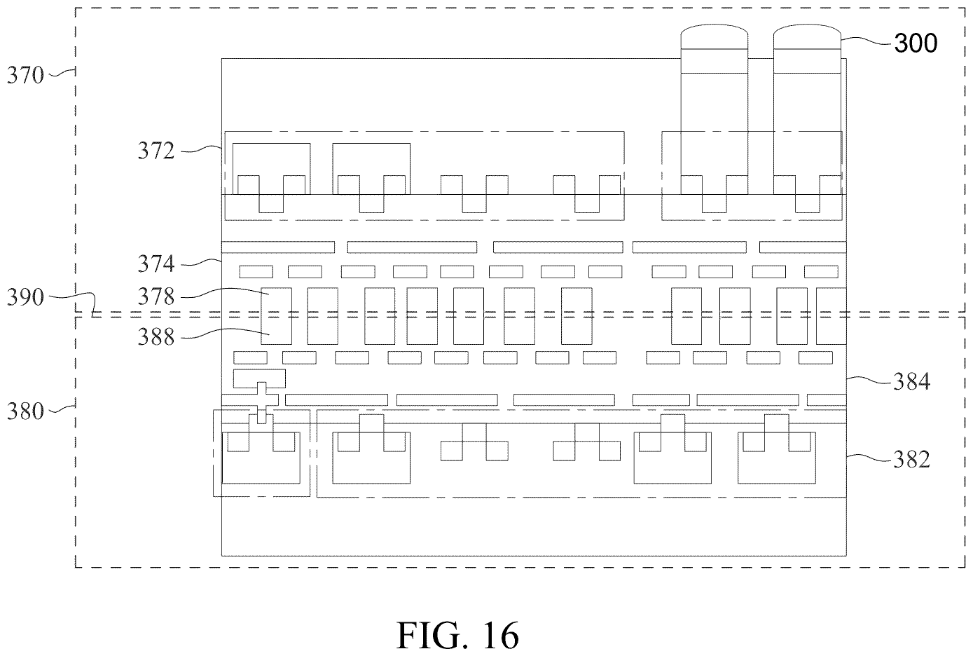

FIG. 16 is a cross-sectional view of a CMOS image sensor (CIS) semiconductor package 370 which is connected to an image signal processor (ISP) semiconductor package 380. The front side of the CIS semiconductor package includes image sensors 300 as described herein on the right-hand side. Transistors 372 on the left-hand side are used for control. An interconnect structure 374 is present on the back side of the CIS semiconductor package. The ISP semiconductor package includes transistors 382 and an interconnect structure 384. The CIS semiconductor package 370 and the ISP semiconductor package 380 are connected to each other through hybrid bonds 390 that use both a dielectric bond and a metal bond. Metal bond pads 378, 388 are present in each package.

The image sensors with a three-sided gate structure of the present disclosure have several advantages. The photodiode stores an electrical charge representing an image signal. However, if the electrical charge is not completely drained when read in a particular frame, then image lag can occur as the residual charge drains in subsequent frames. The buried gate regions of the gate structure increase the effective gate width and create a deeper channel for the electrical charge, permitting more thorough draining and better channel control. This reduces image lag, improving image resolution.

Some embodiments of the present disclosure thus relate to methods for making a semiconductor device. Two trenches are formed in a substrate to form a ridge between a photodiode region and a floating node region. The two trenches are filled with a dielectric material to form isolation regions on either side of the ridge. Two gate trenches are formed in the isolation regions that expose opposite sides of the ridge. A gate dielectric layer is formed on exposed surfaces of the ridge. A gate material is then deposited into the two gate trenches and over the ridge to form a gate structure that comprises two buried gate regions and a capping region over the ridge.

Also described in various embodiments herein are semiconductor devices that comprise a substrate. The substrate comprises a photodiode, a floating node, and a ridge between the photodiode region and the floating node region. A gate dielectric layer is present on the opposite sides of the ridge and over the ridge. A gate structure contacts the gate dielectric layer. The gate structure includes two buried gate regions and a capping region over the ridge.

The present disclosure also relates in various embodiments to methods for using an image sensor. A signal is sent to a gate structure to open a channel between a photodiode and a floating node. The channel is located in a ridge and is surrounded on three sides by a gate dielectric layer and a gate structure. The gate structure includes two buried gate regions and a capping region over the ridge.

Some further embodiments of the present disclosure also relate to semiconductor packages that comprise the semiconductor devices disclosed herein, such as image sensors in different embodiments. The packages may include other components, such as an interconnect structure. Devices including the semiconductor packages or the image sensors described herein are also disclosed.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for making a semiconductor device, comprising:
forming two trenches in a substrate to form a ridge between a photodiode region and a floating node region;
filling the two trenches with a dielectric material to form isolation regions on either side of the ridge;
forming two gate trenches in the isolation regions that expose opposite sides of the ridge;
forming a gate dielectric layer on exposed surfaces of the ridge; and
depositing a gate material into the two gate trenches and over the ridge to form a gate structure that comprises two buried gate regions and a capping region over the ridge.

2. The method of claim 1, further comprising forming a recess in the ridge prior to forming the gate dielectric layer.

3. The method of claim 1, further comprising forming one or more dielectric spacer(s) around the capping region of the gate structure.

4. The method of claim 1, wherein the capping region of the gate structure has a height of about 1000 angstroms to about 3000 angstroms.

5. The method of claim 1, wherein the two buried gate regions independently have a width of about 1000 angstroms to about 3000 angstroms.

6. The method of claim 1, wherein portions of the two buried gate regions proximate the photodiode region are deeper than portions of the two buried gate regions proximate the floating node region.

7. The method of claim 1, further comprising
forming a photodiode in the photodiode region; and
forming a floating node in the floating node region.

8. The method of claim 7, wherein a ratio between a depth of the two buried gate regions to a depth of the photodiode is from about 1:100 to about 100:100.

9. The method of claim 7, wherein a depth of the photodiode is greater than a depth of the floating node.

10. The method of claim 7, wherein the photodiode is formed by:
doping the photodiode region with a first dopant type to form a deep doped region; and
doping the photodiode region with a second dopant type to form a shallow doped region.

11. The method of claim 10, wherein the floating node is formed by:
doping the floating node region with the second dopant type to form a deep doped region; and
doping the floating node region with the first dopant type to form a shallow doped region.

12. The method of claim 11, wherein the first dopant type is an n-type dopant, and the second dopant type is a p-type dopant.

13. A semiconductor device, comprising:
a substrate comprising a photodiode, a floating node, and a ridge between the photodiode and the floating node;
a gate dielectric layer on the opposite sides of the ridge and over the ridge;
a gate structure contacting the gate dielectric layer that comprises two buried gate regions and a capping region over the ridge.

14. The semiconductor device of claim 13, wherein the device comprises a total of four photodiodes, four gate structures, and one floating node, each photodiode being electrically connected through an individual gate structure to the one floating node.

15. The semiconductor device of claim 13, further comprising isolation regions on opposite sides of the ridge.

16. The semiconductor device of claim 13, wherein the ridge comprises a recess which is filled by the gate dielectric layer.

17. The semiconductor device of claim 13, wherein portions of the two buried gate regions proximate the photodiode are deeper than portions of the two buried gate regions proximate the floating node.

18. An image sensor, comprising:
a channel between a photodiode and a floating node;
wherein the channel is surrounded on three sides by a gate dielectric layer and a gate structure, and wherein the gate structure comprises two buried gate regions and a capping region.

19. The method of claim 18, wherein isolation regions are present on opposite sides of the channel, and the two buried gate regions contact the isolation regions.

20. The method of claim 18, further comprising at least one dielectric spacer around the capping region of the gate structure.
